(19) United States
(12) Patent Application Publication
(10) Pub. No.: US 2014/0306731 A1
(43) Pub. Date: Oct. 16, 2014

(54) METHOD OF TESTING SEMICONDUCTOR DEVICE AND SEMICONDUCTOR TESTING SYSTEM

(71) Applicant: INOTERA MEMORIES, INC., Taoyuan County (TW)

(72) Inventor: WEI-CHIH WANG, NEW TAIPEI CITY (TW)

(73) Assignee: INOTERA MEMORIES, INC., Taoyuan County (TW)

(21) Appl. No.: 13/949,407

(22) Filed: Jul. 24, 2013

(30) Foreign Application Priority Data
Apr. 10, 2013 (TW) 102112704

(51) Int. Cl. G01R 31/26; G01Q 60/30

(52) U.S. Cl. CPC G01R 31/2601; G01Q 60/30
USPC 324/754.07

(57) ABSTRACT

A method of testing semiconductor devices is provided includes: exposing one end of the device contact on the surface of the semiconductor; using a scanning probe microscopy apparatus to scan a diagnostic area on the semiconductor; applying a direct current bias between the conductive probe and a substrate of the semiconductor; directing a testing radiation at the diagnostic area to increase amount of free carriers in the device contacts and in the semiconductor layer under the device contacts; and detecting the current flowing through the conductive probe and the substrate, wherein a defect current signal is measured when the probe is in contact with a defective device contact and a normal current signal is measured when the probe is in contact with a normal device contact, wherein the testing radiation increases the current measured to increase the difference between the defect signal and the normal signal.

### BACKGROUND

1. Field of the Invention

The instant disclosure relates to a method of testing semiconductor devices and a semiconductor testing system; in particular, to a method of testing semiconductor devices for detecting conductivity of device contacts and a semiconductor testing system for detecting conductivity of device contacts.

2. Description of Related Art

In general, the source/drain and the gate electrode of the semiconductor device are respectively connected to the bit line and word line by the device contact. The device contact can be formed during the formation of the interlayer insulating layer of the semiconductor. For example, an insulating layer such as a silica layer may firstly be formed on a semiconductor layer, and a plurality of contact holes is then formed by selective removal portion of the insulating layer. Followed by deposition of metal layer on the surface of each of the contact holes, conductive material is filled in the contact holes to for the device contacts. The device contacts having defect may be formed during the formation of the device contacts. In recent years, with the size of the semiconductor is reduced and the density of memory cells is increased, traditional detection techniques such as scanning electron microsope passive voltage contrast method (SEM PVC) has been unable to localize faulty device contacts in the semiconductor.

### SUMMARY OF THE INVENTION

The object of the instant disclosure is to provide a method of testing semiconductor devices and a semiconductor testing system. The method of testing semiconductor devices and the semiconductor testing system utilize a testing radiation directed at a diagnostic area to increase amount of free carriers in the device contacts in the diagnostic area and in the semiconductor layer under the device contacts.

According to one exemplary embodiment of the instant disclosure, a method of testing semiconductor devices is provided, which includes the following steps: exposing one end of each of the device contacts on the surface of the semiconductor; using a scanning probe microscopy apparatus, including a cantilever and a conductive probe disposed at the free end of the cantilever, to scan a diagnostic area on the semiconductor; applying a direct current bias between the conductive probe and a substrate of the semiconductor; directing a testing radiation at the diagnostic area to increase amount of free carriers in the device contacts in the diagnostic area and in the semiconductor layer under the device contacts; and detecting the current flowing through the conductive probe and the substrate, wherein a defect current signal is measured when the conductive probe is in contact with a defective device contact and a normal current signal is measured when the conductivity probe is in contact with a normal device contact wherein the testing radiation increases the current measured to increase the difference between the defect signal and the normal signal.

According to one exemplary embodiment of the instant disclosure, a semiconductor testing system is provided, which includes a cantilever and a conductive probe disposed at the free end of the cantilever, for scanning a diagnostic area on the semiconductor. The voltage supply unit is for applying a direct current bias between the conductive probe and a substrate of the semiconductor. The radiation generating unit is for directing a testing radiation, such as a specific category of light, at the diagnostic area to increase amount of free carriers in the device contacts in the diagnostic area and the semiconductor layer under the device contacts. The current detecting unit is for detecting the current flowing through the conductive probe and the substrate, wherein a defect signal is measured when the conductive probe is in contact with a defective device contact and a normal signal is measured when the conductivity probe is in contact with a normal device contact, wherein the testing radiation increases the current measured to increase the difference between the defect signal and the normal signal.

In order to further understand the instant disclosure, the following embodiments are provided along with illustrations to facilitate the appreciation of the instant disclosure; however, the appended drawings are merely provided for reference and illustration, without any intention to be used for limiting the scope of the instant disclosure.

### BRIEF DESCRIPTION OF THE DRAWINGS

FIG. 1 illustrates a schematic representation view of a semiconductor detecting system in accordance with an embodiment of the instant disclosure in one exemplary application;

FIG. 2 is an enlarged partial schematic representation view of the semiconductor detecting system taken from portion A as shown in FIG. 1 in one exemplary application;

FIG. 3 illustrates a schematic representation view of a radiation generating unit of the semiconductor detecting system in accordance with an embodiment of the instant disclosure;

FIG. 4 is a diagram illustrating a relationship among measured current and direct current bias applied in one exemplary application;

FIG. 5A is a diagram illustrating a relationship among measured current and probe offset in accordance with the semiconductor detecting system of prior art;

FIGS. 5B and 5C are diagrams illustrating a relationship among measured current and probe offset in accordance with an embodiment of the instant disclosure in one exemplary application;

FIG. 6 is a diagram illustrating a relationship among the difference between defect and normal signal measured and light intensity in accordance with an embodiment of the instant disclosure in one exemplary application; and

FIG. 7 is a flow chart of a method of testing semiconductor devices in accordance with one embodiment of the instant disclosure.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

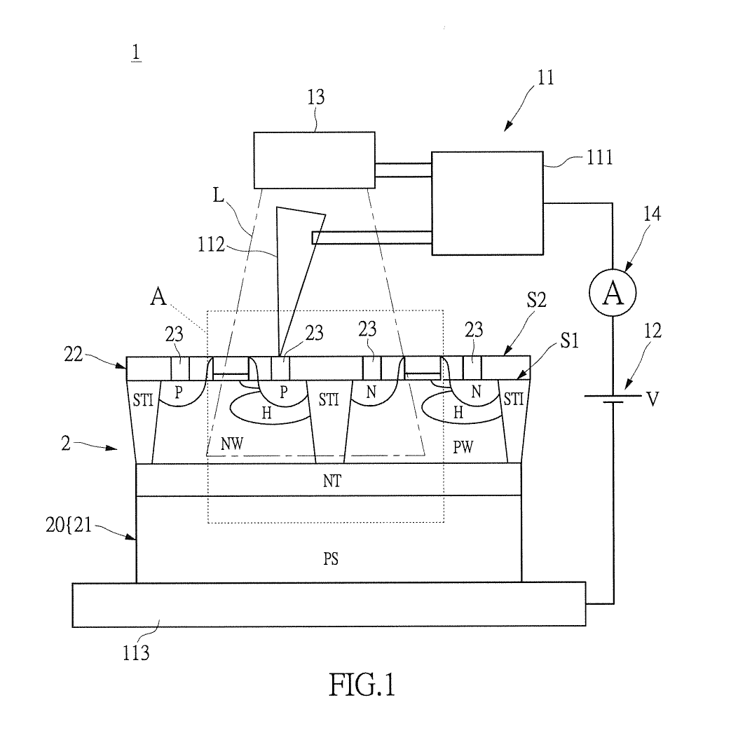

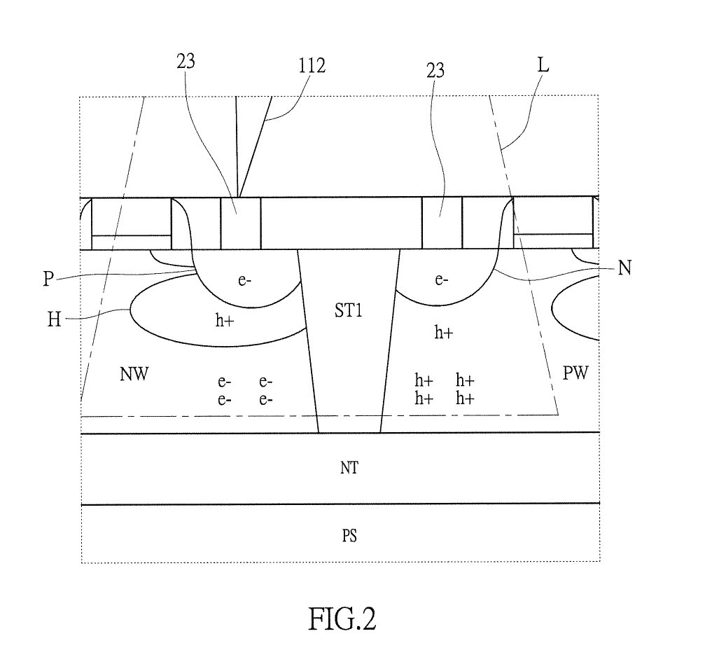

Please refer to FIGS. 1 to 2. FIG. 1 illustrates a schematic representation view of a semiconductor detecting system in accordance with an embodiment of the instant disclosure in one exemplary application, and FIG. 2 is an enlarged partial schematic representation view of the semiconductor detecting system taken from portion A as shown in FIG. 1 in one exemplary application. The semiconductor testing system is for detecting conductivity of device contacts on a semiconductor layer of a semiconductor and includes a scanning probe microscopy apparatus, a voltage supply unit, a radiation generating unit, and a current detecting unit.

The scanning probe microscopy apparatus includes a cantilever and a conductive probe disposed at the free end of the cantilever, for scanning a diagnostic area on the semiconductor. The voltage supply unit is for applying a direct current bias between the conductive probe and a substrate of the semiconductor. The radiation generating unit is for directing a testing radiation, such as a specific category of light, at the diagnostic area to increase amount of free carriers in the device contacts in the diagnostic area and the semiconductor layer under the device contacts. The current detecting unit is for detecting the current flowing through the conductive probe and the substrate, wherein a defect signal is measured when the conductive probe is in contact with a defective device contact and a normal signal is measured when the conductivity probe is in contact with a normal device contact, wherein the testing radiation increases the current measured to increase the difference between the defect signal and the normal signal.

In one exemplary application of the semiconductor testing system, the semiconductor may include a semiconductor layer, an interlayer insulating layer, and at least one device contact. The interlayer insulating layer is disposed on the semiconductor layer, and the device contacts are disposed in and penetrate the interlayer insulating layer. For example, the semiconductor layer may have an array of active areas (active area array) formed thereon, and the active area array can include a plurality of crossingly arranged active area columns and active area rows, forming a plurality of active areas. As shown in FIG. 1 in the instant disclosure, the semiconductor layer can include a based substrate formed of P-type doped silicon. A N-type well, a P-type well, a halo implant area, and a N-type tub area may be formed in the semiconductor layer, and a plurality of shallow trench isolation structures are selectively disposed in the semiconductor layer to define active areas.

A plurality of P-type doped areas can be formed in the active area in the N-type well, and the P-type doped areas serve as source/drain. Thus, a PN junction may be formed near the boundary between the P-type doped area and the N-type well in the vertical direction. A plurality of N-type doped areas can be formed in the active area in the P-type well, and the N-type doped areas serve as source/drain. Thus, a PN junction may be formed near the boundary between the N-type doped area and the P-type well in the vertical direction. One end of the device contact is connected to the doped area, and the other end of the device contact is exposed on the surface of the interlayer insulating layer.

In the method of testing semiconductor devices in the exemplary embodiment, firstly, one end of each of the device contacts is exposed on the surface of the semiconductor. A scanning probe microscopy apparatus, which includes a cantilever and a conductive probe disposed at the free end of the cantilever, is then used to scan a diagnostic area on the semiconductor. Specifically, the conductive probe can be in contact with the exposed end of the device contact in the diagnostic area during scanning. The scanning probe microscopy apparatus is for example a conductive-atomic force microscope. The cantilever and the conductive probe can be made from a semiconductor material such as monocrystalline silicon material. A conductive layer, such as a metal layer or a diamond layer, can be coated on the surface of the conductive probe. In addition, the scanning probe microscopy apparatus can further include a testing stage for carrying the semiconductor to be tested.

Subsequently, a direct current bias is applied between the conductive probe and the substrate of the semiconductor. Specifically, a voltage supply unit, which can be a variable DC power supply and have a first electrode and a second electrode, is used to apply a direct current bias between the conductive probe and a substrate of the semiconductor. The conductive probe is electrically connected to the first electrode of the voltage supply unit, and the substrate of the semiconductor is electrically connected to the second electrode of the voltage supply unit. To put it concretely, the conductive probe is electrically connected to the first electrode through the cantilever, and the substrate of the semiconductor is electrically connected to the second electrode through the testing stage. For example, a forward direct current bias is applied between the conductive probe and the substrate of the semiconductor.

A testing radiation, such as a specific category of light irradiation, is directed at the diagnostic area during the scanning to increase amount of free carriers in the device contacts in the diagnostic area and the semiconductor layer under the device contacts. In the instant disclosure, the testing radiation directed at the diagnostic area during the scanning can increase amount of free carriers in a N-type doped area, a P-type doped area, a N-type well, a P-type well, and a halo implant area in the semiconductor layer to increase amount of free carriers in the device contacts in the diagnostic area and in the semiconductor layer under the device contacts. Specifically, a radiation generating unit is used to direct a testing radiation at the diagnostic area. The radiation generating unit can be attached to the cantilever and arranged above the conductive probe. When the conductive probe moves to the diagnostic area, the testing radiation is accordingly directed at the diagnostic area.

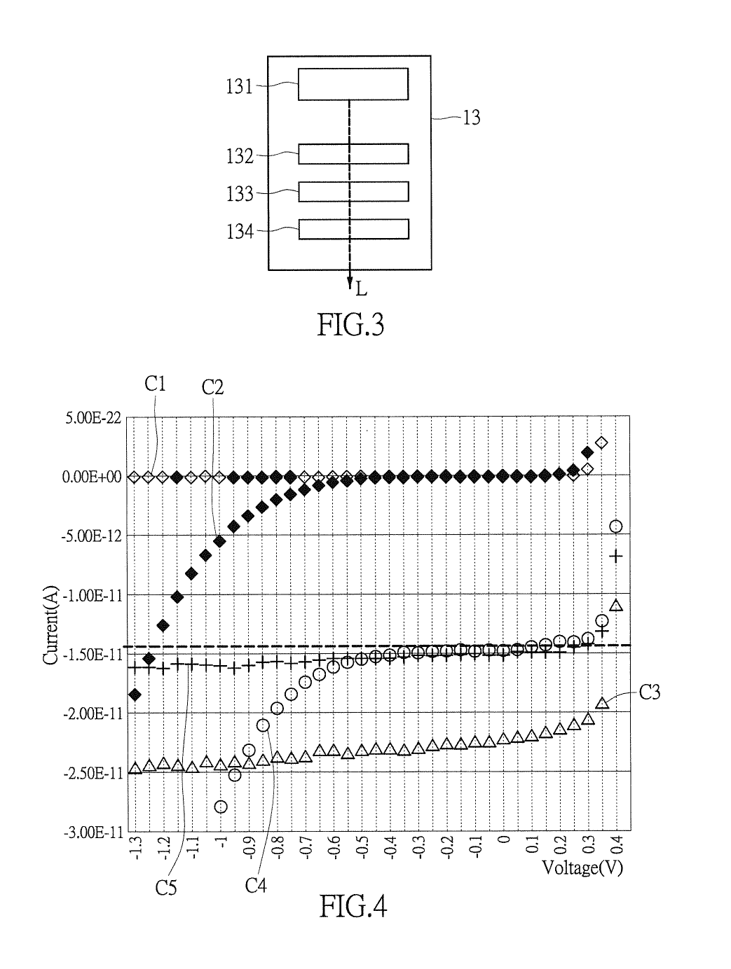

Please refer to FIG. 3, which illustrates a schematic representation view of a radiation generating unit of the semiconductor detecting system in accordance with an embodiment of the instant disclosure. The radiation generating unit for example includes a radiation source, a convergent lens, a divergent lens, and a shielding aperture. The radiation source such as a visible light source is for emitting the radiation to form a radiation path. The convergent lens, the divergent lens and the shielding aperture are sequentially arranged on the radiation path. Thus, the radiation emitted from the radiation source can pass through the convergent lens, the divergent lens and the shielding aperture in sequence to form a testing radiation.

In the instant disclosure, the testing radiation is perpendicularly directed at the diagnostic area on the surface of the semiconductor. The testing radiation for example has a wavelength ranging from 800 to 1240 nm. The testing radiation directed at the diagnostic area during the scanning can irradiate free carriers in the semiconductor layer to increase amount of free carriers in the device contacts in the diagnostic area and in the semiconductor layer under the device contacts. As shown in FIG. 2, free carriers such as electrons are generated in at least a portion of the N-type well, at least a portion of the P-type doped area, and at least a portion of the N-type doped area in the diagnostic area where the testing radiation is directed at. Free carriers such as holes are generated in at least a portion of the P-type well and at least a portion of the halo implant area in the diagnostic area where the testing radiation is directed at.

It is worth to note that, the category and the intensity of the testing radiation directed at the diagnostic area can be specified. For example, in one embodiment, the testing radiation has a wavelength ranging from 350 to 800 nm and has the intensity on the surface of the semiconductor ranging from 300 to 6000 lx. In another embodiment, the testing radiation has a wavelength ranging from 800 to 1240 nm and has the intensity on the surface of the semiconductor greater than 0.5 milliwatts per square centimeter. In another embodiment, the testing radiation can be a laser beam.

Subsequently, detecting the current flowing through the conductive probe and the substrate is carried out, wherein a defect current signal is measured when the conductive probe is in contact with a defective device contact and a normal current signal is measured when the conductivity probe is in contact with a normal device contact. Specifically, a current detecting unit including a current meter can be used for detecting the current flowing through the conductive probe and the substrate. The testing radiation increases the current measured to increase the difference between the defect signal and the normal signal.

Please refer to FIG. 4, which is a diagram illustrating a relationship among measured current and direct current bias applied in one exemplary application. In FIG. 4, the X axis represents the value of the direct current bias, in units of volts, applied between the conductive probe and the substrate of the semiconductor, while the Y axis represents the measured current signal, which is the value of the detected current, in units of amps, flowing through the conductive probe and the substrate. In one exemplary application of the method of testing semiconductor devices, by completing the final step of detecting the current flowing through the conductive probe and the substrate, the conductivity of device contacts, such as the PN junction leakage characteristics of device contacts, can be tested.

To put it concretely, as shown in FIG. 4, curve C1 and curve C2 are respectively the I/V curve of a normal device contact and the I/V curve of a defect device contact measured by prior art. Curve C3 is the I/V curve of a normal device contact measured in accordance with an embodiment of the instant disclosure. Curve C4 and curve C5 are the I/V curves of a defect device contact measured in accordance with an embodiment of the instant disclosure. The current measured is increased by the testing radiation. Hence, the difference between the defect signal and the normal signal is increased. Specifically, under an applied direct current bias having substantially the same voltage level, the value of the current (defect signal) measured when the conductivity probe is in contact with a defective device contact, which is represented by curve C4 and curve C5, is greater than the value of the current (normal signal measured) when the conductive probe is in contact with a normal device contact which is represented by curve C3. In other words, the device contacts, which curve C4 and curve C5 respectively refer to, have defect resulting in PN junction leakage.

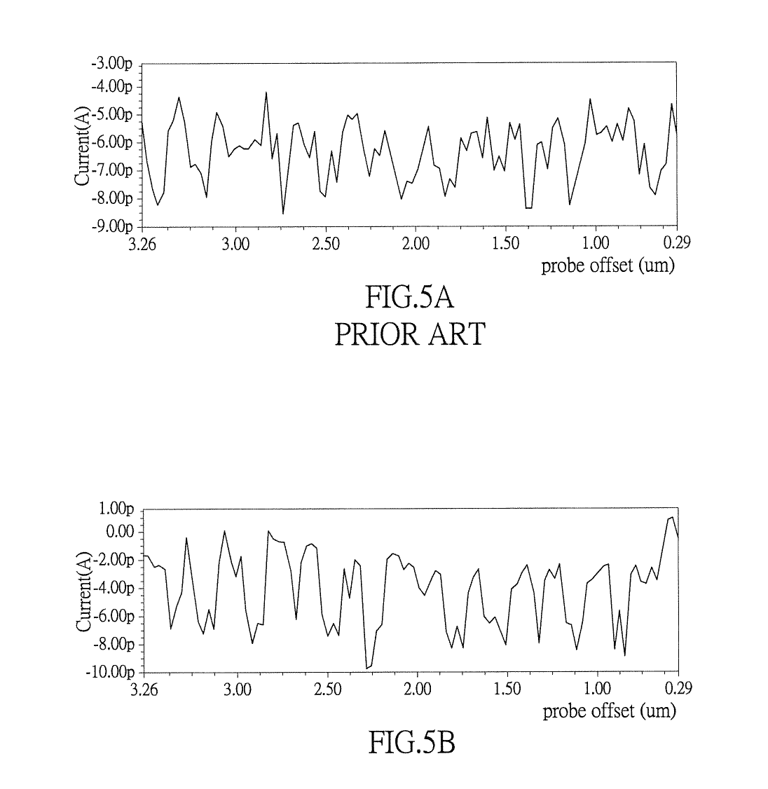

Please further refer to FIGS. 5A, 5B, and 5C. FIG. 5A is a diagram illustrating a relationship among measured current and probe offset by prior art, and FIGS. 5B and 5C are diagrams illustrating a relationship among measured current and probe offset in accordance with an embodiment of the instant disclosure in one exemplary application. In FIGS. 5A, 5B, and 5C, the X axis represents the offset distance of the conductive probe, in units of micrometers, while the Y axis represents the measured current signal, which is the value of the detected current, in units of amps, flowing through the conductive probe and the substrate. In one exemplary application of the method of testing semiconductor devices, by completing the final step of detecting the current flowing through the conductive probe and the substrate, the conductivity of device contacts of device contacts can be tested as to localize faulty device contacts.

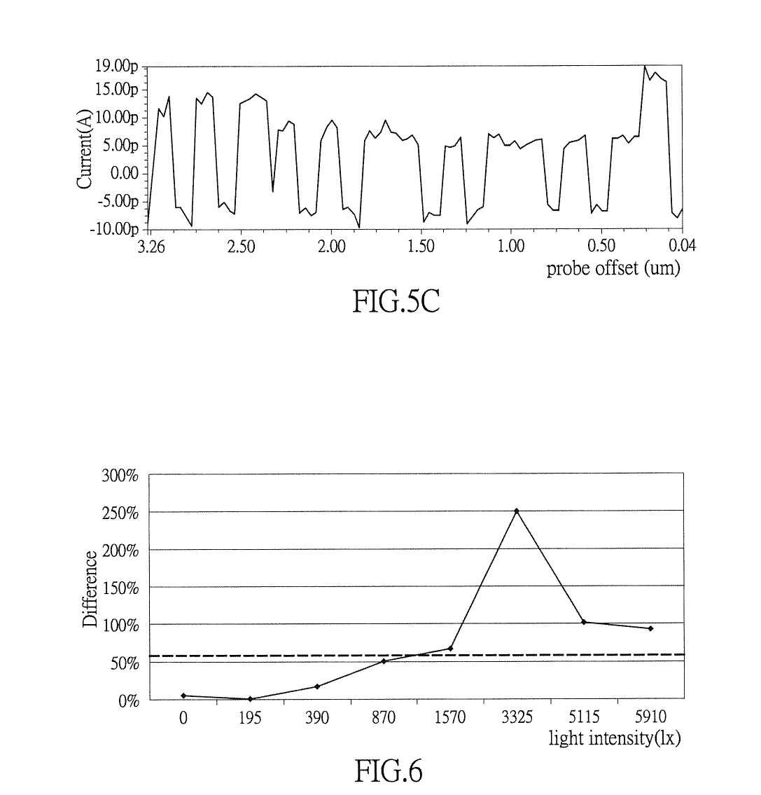

Please refer to FIG. 6, which is a diagram illustrating a relationship among the difference between defect and normal signal measured and light intensity in accordance with an embodiment of the instant disclosure in one exemplary application. In FIG. 6, the X axis represents the intensity of the testing radiation, in units of lux, directed at the diagnostic area, while the Y axis represents the difference between defect and normal signal measured, in percentage. In one exemplary application of the method of testing semiconductor devices and the semiconductor testing system, with the increase of the intensity of the testing radiation directed at the diagnostic area, the difference between defect and normal signal measured increases in general. When the value of the intensity of the testing radiation directed at the diagnostic area falls within a certain range, the difference between defect and normal signal measured is large. the difference between defect and normal signal measured may reach 50%, that is, the recognition rate is high.

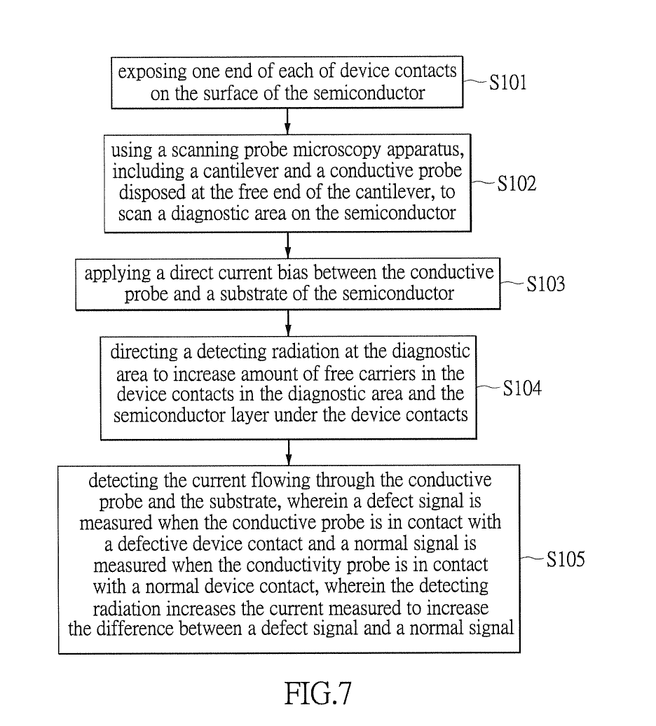

Attention is now invited to FIG. 7, which is a flow chart of a method of testing semiconductor devices in accordance with one embodiment of the instant disclosure. A method of testing semiconductor devices for detecting conductivity of device contacts on a semiconductor layer of a semiconductor in accordance with one embodiment of the instant disclosure includes the steps of: exposing one end of each of the device contacts on the surface of the semiconductor (step S101); using a scanning probe microscopy apparatus, including a cantilever and a conductive probe disposed at the free end of the cantilever, to scan a diagnostic area on the semiconductor (step S102); applying a direct current bias between the conductive probe and a substrate of the semiconductor (step S103); directing a testing radiation at the diagnostic area to increase amount of free carriers in the device contacts in the diagnostic area and in the semiconductor layer under the device contacts (step S104); and detecting the current flowing through the conductive probe and the substrate, wherein a defect current signal is measured when the conductive probe is in contact with a defective device contact and a normal current signal is measured when the conductivity probe is in contact with a normal device contact wherein the testing radiation increases the current measured to increase the difference between the defect signal and the normal signal (step S105).

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A method of testing semiconductor devices for detecting conductivity of device contacts on a semiconductor layer of a semiconductor, comprising the following steps:
exposing one end of each of the device contacts on the surface of the semiconductor ;
using a scanning probe microscopy apparatus, including a cantilever and a conductive probe disposed at the free end of the cantilever, to scan a diagnostic area on the semiconductor;
applying a direct current bias between the conductive probe and a substrate of the semiconductor;
directing a testing radiation at the diagnostic area to increase amount of free carriers in the device contacts in the diagnostic area and the semiconductor layer under the device contacts; and
detecting the current flowing through the conductive probe and the substrate, wherein a defect signal is measured when the conductive probe is in contact with a defective device contact and a normal signal is measured when the conductivity probe is in contact with a normal device contact;
wherein the testing radiation increases the current measured to increase the difference between a defect signal and a normal signal.

2. The method of testing semiconductor devices according to claim 1, wherein the testing radiation has a wavelength ranging from 350 to 800 nm and has an intensity on the surface of the semiconductor ranging from 300 to 6000 lx.

3. The method of testing semiconductor devices according to claim 1, wherein the testing radiation has a wavelength ranging from 800 to 1240 nm and has an intensity on the surface of the semiconductor greater than 0.5 milliwatts per square centimeter.

4. The method of testing semiconductor devices according to claim 1, wherein the testing radiation is perpendicularly directed at the diagnostic area on the surface of the semiconductor.

5. The method of testing semiconductor devices according to claim 1, wherein the testing radiation is a laser beam.

6. A semiconductor detecting system for localizing faulty device contacts on a semiconductor layer, comprising:
a scanning probe microscopy apparatus, including a cantilever and a conductive probe disposed at the free end of the cantilever, for scanning a diagnostic area on the semiconductor;
a voltage supply unit for applying a direct current bias between the conductive probe and a substrate of the semiconductor;
a radiation generating unit for directing a testing radiation at the diagnostic area to increase amount of free carriers in the device contacts in the diagnostic area and the semiconductor layer under the device contacts; and
a current detecting unit for detecting the current flowing through the conductive probe and the substrate, wherein a defect signal is measured when the conductive probe is in contact with a defective device contact and a normal signal is measured when the conductivity probe is in contact with a normal device contact;
wherein the testing radiation increases the current measured to increase the difference between a defect signal and a normal signal.

7. The semiconductor detecting system according to claim 6, wherein the radiation generating unit includes a radiation source, a collector lens, a diffusion lens, and a condenser aperture, the radiation source is for emitting the radiation to form a radiation path, and the collector lens, the diffusion lens and the condenser aperture are sequentially arranged on the radiation path.

8. The semiconductor detecting system according to claim 6, wherein the radiation generating unit is attached to the cantilever and arranged above the conductive probe, and when the conductive probe moves to the diagnostic area, the testing radiation is accordingly directed at the diagnostic area.

9. The semiconductor detecting system according to claim 6, wherein the testing radiation has a wavelength ranging from 350 to 800 nm and has an intensity on the surface of the semiconductor ranging from 300 to 6000 lx.

10. The semiconductor detecting system according to claim 6, wherein the testing radiation has a wavelength ranging from 800 to 1240 nm and has an intensity on the surface of the semiconductor greater than 0.5 milliwatts per square centimeter.
